(19) United States
(12) Patent Application Publication
(10) Pub. No.: US 2020/0220116 A1
(43) Pub. Date: Jul. 9, 2020

(54) METHOD FOR MANUFACTURING ORGANIC ELECTROLUMINESCENCE DEVICE, ORGANIC ELECTROLUMINESCENCE DEVICE, AND ELECTRONIC APPARATUS

(71) Applicant: SEIKO EPSON CORPORATION, Tokyo (JP)

(72) Inventors: Takefumi FUKAGAWA, Suwa-gun (JP); Suguru AKAGAWA, Matsumoto-shi (JP); Ryoichi NOZAWA, Kamiina-gun (JP)

(73) Assignee: SEIKO EPSON CORPORATION, Tokyo (JP)

(21) Appl. No.: 16/737,091

(22) Filed: Jan. 8, 2020

(30) Foreign Application Priority Data
Jan. 9, 2019 (JP) 2019-001684

(51) Int. Cl. H01L 51/56

(52) U.S. Cl. CPC H01L 51/56; H01L 2251/303

(57) ABSTRACT

A method for manufacturing an organic electroluminescence device includes forming an organic electroluminescence element on a substrate, forming, on the organic electroluminescence element, a first layer mainly composed of a silicon-based inorganic material containing nitrogen by a chemical vapor deposition method using plasma, and forming, on the first layer, a second layer mainly composed of silicon oxide by an atomic layer deposition method using plasma.

The present application is based on, and claims priority from JP Application Serial Number 2019-001684, filed Jan. 9, 2019, the disclosure of which is hereby incorporated by reference herein in its entirety.

### BACKGROUND

### 1. Technical Field

The present disclosure relates to a method for manufacturing an organic electroluminescence device, an organic electroluminescence device, and an electronic apparatus.

### 2. Related Art

Organic electroluminescence (EL) devices including organic light-emitting diodes (OLEDs) are known. The organic EL device is used as, for example, an organic EL display configured to display an image.

An organic EL display described in JP-T-2011-517302 includes an organic light-emitting diode (OLED) and a cover portion that protects the OLED from moisture and oxygen. The cover portion includes a first layer made of silicon nitride formed by a chemical vapor deposition (CVD) method, and a second layer made of aluminum oxide formed by an atomic layer deposition (ALD) method.

The cover portion having excellent sealing performance and a thin thickness can be formed by providing the first layer formed by the CVD method and the second layer formed by the ALD method. However, the second layer made of aluminum oxide is less resistant to water than the first layer made of silicon nitride. Thus, there is a risk that, when, for example, water washing processing or processing by wet etching is performed in manufacturing the organic EL device, the second layer dissolves during the processing. As a result, there is a risk that the sealing performance of the cover portion is impaired, and thus there is a problem in that quality reliability of the organic EL device decreases.

### SUMMARY

One aspect of a method for manufacturing an organic electroluminescence device in the present disclosure includes forming an organic electroluminescence element on a substrate, forming, on the organic electroluminescence element, a first layer mainly composed of a silicon-based inorganic material containing nitrogen by a chemical vapor deposition method using plasma, and forming, on the first layer, a second layer mainly composed of silicon oxide by an atomic layer deposition method using plasma.

One aspect of an organic electroluminescence device in the present disclosure includes a substrate, an organic electroluminescence element disposed on the substrate, a first layer disposed on a side opposite to the substrate with respect to the organic electroluminescence element, and mainly composed of a silicon-based inorganic material containing nitrogen, and a second layer disposed on a side opposite to the organic electroluminescence element with respect to the first layer, and mainly composed of silicon oxide.

### BRIEF DESCRIPTION OF THE DRAWINGS

FIG. 1 is a perspective view illustrating an organic EL device according to a first embodiment.

FIG. 2 is a schematic plan view illustrating a display panel according to the first embodiment.

FIG. 3 is a block diagram illustrating an electrical configuration of the display panel according to the first embodiment.

FIG. 4 is an equivalent circuit diagram of a sub-pixel according to the first embodiment.

FIG. 5 is a partial cross-sectional view of the display panel according to the first embodiment.

FIG. 6 is a partial cross-sectional view of the display panel according to the first embodiment.

FIG. 7 is a flowchart illustrating a method for manufacturing the display panel according to the first embodiment.

FIG. 8 is a cross-sectional view illustrating a substrate formation step and a light-emitting portion formation step according to the first embodiment.

FIG. 9 is a cross-sectional view illustrating a protecting portion formation step according to the first embodiment.

FIG. 10 is a cross-sectional view illustrating the protecting portion formation step according to the first embodiment.

FIG. 11 is a cross-sectional view illustrating the protecting portion formation step according to the first embodiment.

FIG. 12 is a cross-sectional view illustrating the protecting portion formation step according to the first embodiment.

FIG. 13 is a diagram illustrating a color filter layer formation step according to the first embodiment.

FIG. 14 is a diagram illustrating the color filter layer formation step according to the first embodiment.

FIG. 15 is a diagram illustrating the color filter layer formation step according to the first embodiment.

FIG. 16 is a diagram illustrating the color filter layer formation step according to the first embodiment.

FIG. 17 is a diagram illustrating an etching step according to the first embodiment.

FIG. 18 is a partial cross-sectional view of a display panel according to a second embodiment.

FIG. 19 is a partial cross-sectional view of a display panel according to a third embodiment.

FIG. 20 is a plan view schematically illustrating a part of a virtual display apparatus as an example of an electronic apparatus in the present disclosure.

FIG. 21 is a perspective view illustrating a personal computer as an example of the electronic apparatus in the present disclosure.

### DESCRIPTION OF EXEMPLARY EMBODIMENTS

Preferred embodiments of the present disclosure will be described below with reference to the accompanying drawings. Note that, in the drawings, dimensions and scales of sections are differed from actual dimensions and scales as appropriate, and some of the sections are schematically illustrated to make them easily recognizable. Further, the scope of the present disclosure is not limited to these embodiments unless otherwise stated to limit the present disclosure in the following descriptions.

### 1. Organic Electroluminescence (EL) Device and Method for Manufacturing Organic EL Device

### 1-1. First Embodiment

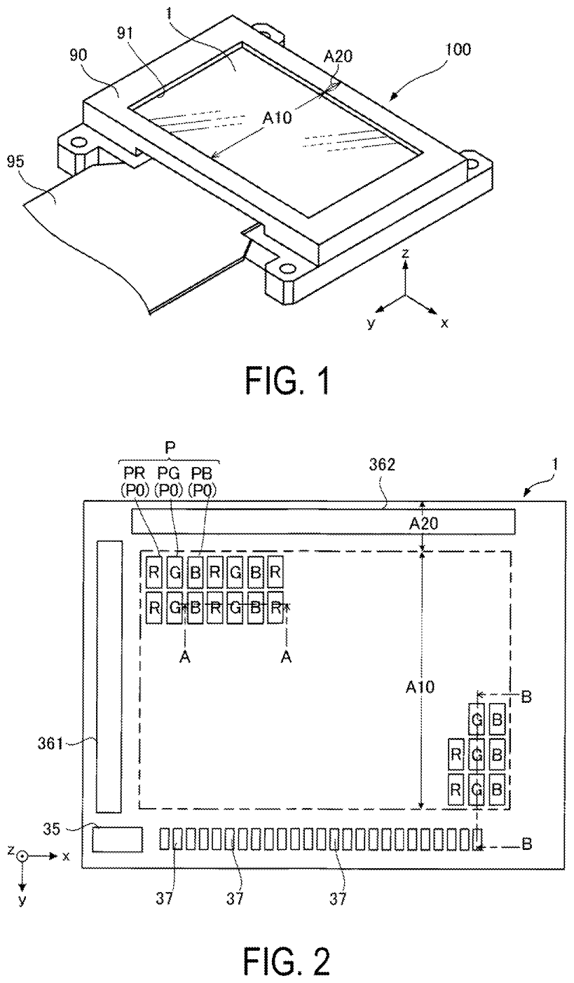

FIG. 1 is a perspective view illustrating a configuration of an organic EL device 100 according to a first embodiment. Note that, for convenience of explanation, the description will be made appropriately using an x-axis, a y-axis, and a z-axis orthogonal to each other illustrated in FIG. 1. A surface of a transmissive substrate 7 included in the display panel 1 described later is parallel to an x-y plane, and a lamination direction of a plurality of layers included in the display panel 1 described later is a z direction.

1-1A. Overall Configuration of Organic EL Device

The organic EL device 100 illustrated in FIG. 1 is an example of an “organic electroluminescence device”, and is an organic EL display device configured to display a full color image. The organic EL device 100 is used as a micro display configured to display an image in a head-mounted display, for example. Note that the head-mounted display will be described later in detail.

The organic EL device 100 includes a case 90 including an opening 91, a display panel 1 provided in the case 90, and a flexible printed circuit (FPC) substrate 95 electrically coupled to the display panel 1. Note that, although not illustrated, the FPC substrate 95 is coupled to an upper circuit provided outside. Further, the organic EL device 100 includes a light-emitting region A10 in which an image is displayed, and a non-light-emitting region A20 surrounding the light-emitting region A10. Note that the light-emitting region A10 has a rectangular shape in plan view as illustrated in the drawings, but a planar shape of the light-emitting region A10 is not limited to this, and may be, for example, circular or the like. The plan view refers to viewing from a -z direction.

FIG. 2 is a schematic plan view illustrating the display panel 1 according to the first embodiment. As illustrated in FIG. 2, a plurality of sub-pixels P0 are provided in matrix of M rows and N columns in the light-emitting region A10 of the display panel 1. Specifically, a plurality of sub-pixels PB corresponding to a blue wavelength region, a plurality of sub-pixels PG corresponding to a green wavelength region, and a plurality of sub-pixels PR corresponding to a red wavelength region are provided in the light-emitting region A10 of the display panel 1. Note that, in the present specification, when the sub-pixel PB, the sub-pixel PG, and the sub-pixel PR are not differentiated, they are expressed as the sub-pixel P0. The sub-pixels PB, the sub-pixels PG, and the sub-pixels PR are arranged in the same color along a y direction, and are arranged repeatedly in the order of red, green, and blue along an x direction. Note that the arrangement of the sub-pixels PB, the sub-pixels PG, and the sub-pixels PR is not limited to this, and any arrangement may be used. Further, one pixel P is constituted of one sub-pixel PB, one sub-pixel PG, and one sub-pixel PR.

Further, a control circuit 35, a scanning line drive circuit 361, and a data line drive circuit 362 are provided in the non-light-emitting region A20 of the display panel 1. Further, a plurality of terminals 37 coupled to the FPC substrate 95 are provided in the non-light-emitting region A20 of the display panel 1. Further, the display panel 1 is coupled to a power supply circuit (not illustrated).

Note that the organic EL device 100 may have a configuration in which the case 90 and the FPC substrate 95 are omitted.

1-1B. Electrical Configuration of Display Panel 1

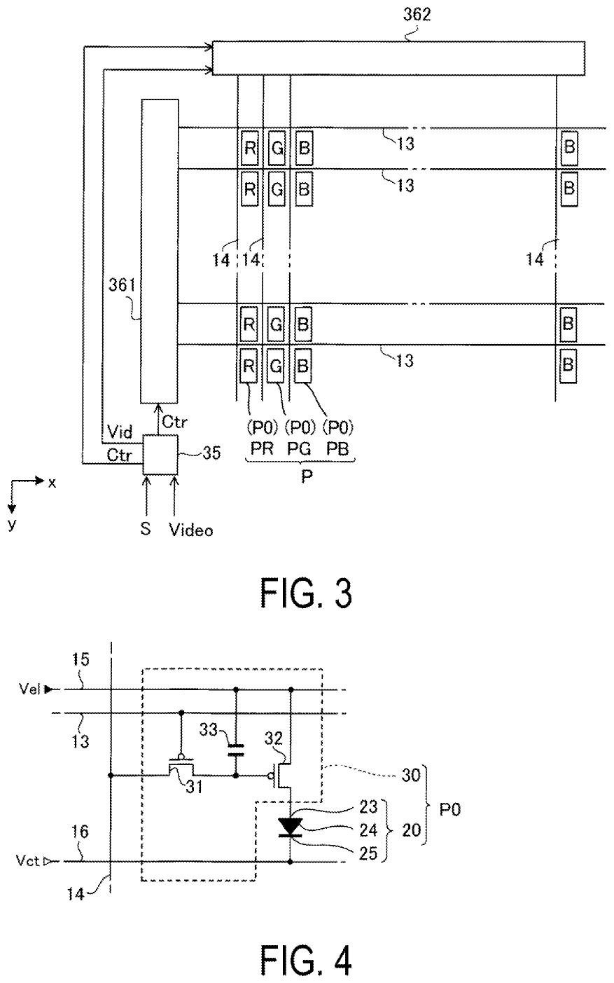

FIG. 3 is a block diagram illustrating an electrical configuration of the display panel 1 according to the first embodiment. As illustrated in FIG. 3, the display panel 1 includes M scanning lines 13 extending along the x direction, and N data lines 14 intersecting the scanning lines 13 and extending along the y direction. Note that M and N are natural numbers. Further, the plurality of sub-pixels P0 are constituted so as to correspond to intersections between the M scanning lines 13 and the N data lines 14.

The control circuit 35 is configured to control display of an image. Image data Video, which is digital, is supplied from the upper circuit (not illustrated) synchronously with a synchronization signal S to the control circuit 35. The control circuit 35 generates a control signal Ctr based on the synchronization signal S, and supplies the control signal Ctr to the scanning line drive circuit 361 and the data line drive circuit 362. Further, the control circuit 35 generates an image signal Vid, which is analog, based on the image data Video, and supplies the image signal Vid to the data line drive circuit 362. Note that the image data Video described above is data specifying a gradation level of the sub-pixels P0 by, for example, eight bits. The synchronization signal S is a signal including a vertical synchronization signal, a horizontal synchronization signal, and a dot clock signal.

The scanning line drive circuit 361 is coupled to the M scanning lines 13. Based on the control signal Ctr, the scanning line drive circuit 361 generates a scanning signal for sequentially selecting the M scanning lines 13 one by one within one frame period, and outputs the generated scanning signal to the M scanning lines 13. Further, the data line drive circuit 362 is coupled to the N data lines 14. Based on the image signal Vid and the control signal Ctr, the data line drive circuit 362 generates a data signal according to gradation to be displayed, and outputs the generated data signal to the N data lines 14.

Note that the scanning line drive circuit 361 and the data line drive circuit 362 may be integrated as one drive circuit. Further, the control circuit 35, the scanning line drive circuit 361, and the data line drive circuit 362 may each be divided into a plurality of circuits. Further, as illustrated in the drawings, the control circuit 35 is provided on the display panel 1, but the control circuit 35 may be provided on the FPC substrate 95 illustrated in FIG. 1, for example.

FIG. 4 is an equivalent circuit diagram of the sub-pixel P0 according to the first embodiment. As illustrated in FIG. 4, the sub-pixel P0 is provided with a light-emitting element 20 and a pixel circuit 30 that controls driving of the light-emitting element 20.

The light-emitting element 20 is an example of an “organic electroluminescence element”, and is constituted of an organic light emitting diode (OLED). The light-emitting element 20 includes an anode 23, an organic layer 24, and a cathode 25. The anode 23 supplies holes to the organic layer 24. The cathode 25 supplies electrons to the organic layer 24. In the light-emitting element 20, the holes supplied from the anode 23 and the electrons supplied from the cathode 25 are recombined in the organic layer 24, and the organic layer 24 emits white light. Note that a power supplying line 16 is electrically coupled to the cathode 25. A power supply potential Vct on a low potential side is supplied from the power supply circuit (not illustrated) to the power supplying line 16.

The pixel circuit 30 includes a switching transistor 31, a driving transistor 32, and a retention capacitor 33. A gate of the switching transistor 31 is electrically coupled to the scanning line 13. Further, one of a source and a drain of the switching transistor 31 is electrically coupled to the data line 14, and the other is electrically coupled to a gate of the driving transistor 32. Further, one of a source and a drain of the driving transistor 32 is electrically coupled to the power supplying line 15, and the other is electrically coupled to the anode 23. Note that a power supply potential Vel on a high potential side is supplied from the power supply circuit (not illustrated) to the power supplying line 15. Further, one of electrodes of the retention capacitor 33 is coupled to the gate of the driving transistor 32, and the other electrode is coupled to the power supplying line 15.

In the display panel 1 having the electrical configuration, when the scanning line 13 is selected by activating the scanning signal by the scanning line drive circuit 361, the switching transistor 31 provided in the selected sub-pixel P0 is turned on. Then, the data signal is supplied from the data line 14 to the driving transistor 32 corresponding to the selected scanning line 13. The driving transistor 32 supplies a current corresponding to a potential of the supplied data signal, that is, a current corresponding to a potential difference between the gate and the source, to the light-emitting element 20. Then, the light-emitting element 20 emits light at a luminance corresponding to a magnitude of the current supplied from the driving transistor 32. Further, when the scanning line drive circuit 361 releases the selection of the scanning line 13 and the switching transistor 31 is turned off, the potential of the gate of the driving transistor 32 is held by the retention capacitor 33. Thus, the light-emitting element 20 can emit light even after the switching transistor 31 is turned off.

The electrical configuration of the display panel 1 is described above. Note that the configuration of the pixel circuit 30 described above is not limited to the illustrated configuration. For example, a transistor that controls conduction between the anode 23 and the driving transistor 32 may be further provided.

1-1C. Configuration of Display Panel 1

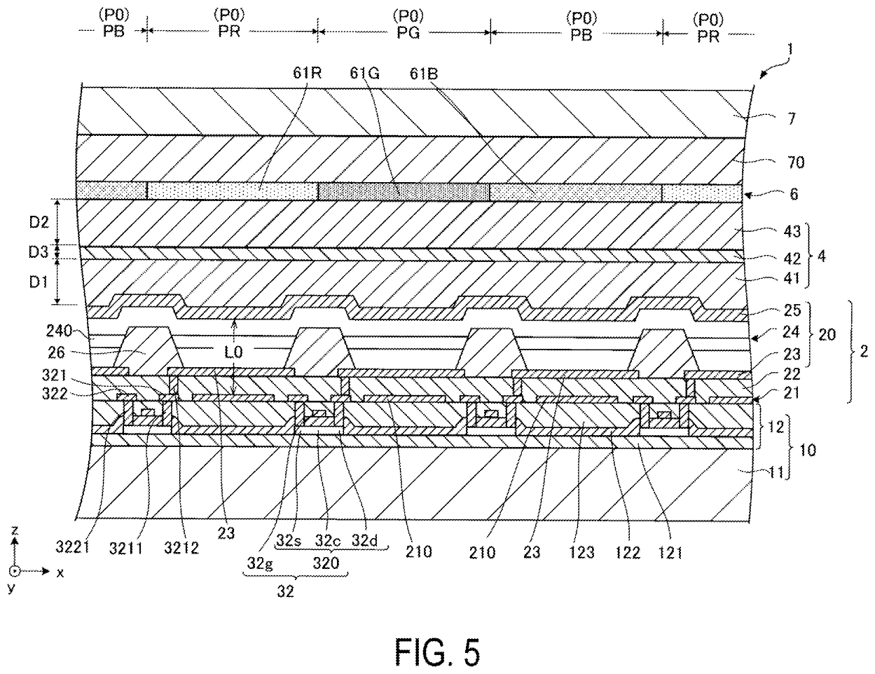

FIG. 5 is a partial cross-sectional view of the display panel 1 according to the first embodiment, and is a cross-sectional view of the display panel 1 taken along an A-A line in FIG. 2. In the following description, “translucency” refers to transparency to visible light, and means that a transmittance of visible light may be greater than or equal to 50%. Further, “light reflectivity” refers to reflectivity to visible light, and means that a reflectance of visible light may be greater than or equal to 50%.

The display panel 1 illustrated in FIG. 5 includes a substrate 10, a light-emitting portion 2 including the plurality of light-emitting elements 20, a protecting portion 4, a color filter layer 6, and the transmissive substrate 7. The light-emitting portion 2, the protecting portion 4, and the color filter layer 6 are laminated in this order from the substrate 10 toward the transmissive substrate 7. The display panel 1 is top-emission type, and light generated from the light-emitting element 20 is transmitted through the transmissive substrate 7 and emitted.

Substrate 10

The substrate 10 includes a substrate main body 11 made of silicon, for example, and a wiring layer 12. The substrate main body 11 is made of silicon, glass, resin, ceramic, or the like, for example. Further, the display panel 1 is a top-emission type, and thus the substrate main body 11 may or may not have translucency.

The wiring layer 12 includes various wiring lines and the like and a plurality of insulating films 121, 122, and 123. Various wiring lines and the like include the pixel circuit 30 including the switching transistor 31, the driving transistor 32, and the retention capacitor 33 described above, the scanning line 13, the data line 14, the power supplying line 15, and the power supplying line 16. Note that FIG. 5 does not illustrate all of the various wiring lines.

The insulating film 121 of the wiring layer 12 is disposed on the substrate main body 11. A semiconductor layer 320 included in the driving transistor 32 is disposed on the insulating film 121. The semiconductor layer 320 has a channel 32c, a drain 32d, and a source 32s. Note that, when the substrate main body 11 is silicon, ions may be injected into the substrate main body 11 to form the semiconductor layer 320. Further, the insulating film 122 is disposed on the insulating film 121 so as to cover the semiconductor layer 320. A gate electrode 32g of the driving transistor 32 is disposed on the insulating film 122. The gate electrode 32g overlaps the channel 32c in a plan view. The insulating film 123 is disposed on the insulating film 122 so as to cover the gate electrode 32g. Relay electrodes 321 and 322 are disposed on the insulating film 123. The relay electrode 321 is electrically coupled to the drain 32d via a through electrode 3211 disposed in a contact hole that penetrates the insulating film 122. On the other hand, the relay electrode 322 is electrically coupled to the source 32s via the through electrode 3221 disposed in the contact hole that penetrates the insulating film 122. Note that, although not illustrated in FIG. 5, the relay electrode 322 is coupled to the power supplying line 15.

Examples of a constituent material of the insulating films 121, 122, and 123 include silicon-based inorganic materials such as silicon oxide, silicon nitride, and silicon oxynitride. Further, examples of a constituent material of various wiring lines and the like include metal, metal silicide, and a metal compound, for example.

Light-Emitting Portion 2

The light-emitting portion 2 that resonates light in a predetermined wavelength region is disposed on a surface of the substrate 10 on the +z side. The light-emitting portion 2 includes a reflection layer 21, a resonance adjustment layer 22, and the plurality of light-emitting elements 20. As described above, the plurality of light-emitting elements 20 include the plurality of anodes 23, the organic layer 24, and the cathode 25.

The reflection layer 21 is disposed on the insulating film 123 of the substrate 10. The reflection layer 21 has light reflectivity, and reflects light generated from the organic layer 24 toward the organic layer 24 side. The reflection layer 21 is, for example, a laminate in which a layer containing titanium (Ti) and a layer containing an Al-Cu alloy are laminated in this order on the insulating film 123. Further, as illustrated in the drawings, the reflection layer 21 includes a plurality of reflection portions 210 arranged in matrix. The reflection portion 210 is provided for each sub-pixel P0. Note that the reflection layer 21 is not limited to the illustrated configuration as long as the reflection layer 21 has light reflectivity.

The resonance adjustment layer 22 is disposed on the insulating film 123 so as to cover the reflection layer 21. The resonance adjustment layer 22 is a layer that adjusts an optical distance L0 being an optical distance between the reflection layer 21 and the cathode 25.

As illustrated in the drawing, a thickness of the resonance adjustment layer 22 is equal in the sub-pixels PB, PG, and PR, but actually varies for each light emission color. Further, the optical distance L0 of the sub-pixel P0 varies for each light emission color. The optical distance L0 in the sub-pixel PB is set so as to correspond to light in a blue wavelength region. The optical distance L0 in the sub-pixel PG is set so as to correspond to light in a green wavelength region. The optical distance L0 in the sub-pixel PR is set so as to correspond to light in a red wavelength region. Therefore, in fact, a film thickness of the resonance adjustment layer 22 in the sub-pixel PB is the thinnest, and a film thickness of the resonance adjustment layer 22 in the sub-pixel PR is the thickest. Note that the optical distance L0 may be adjusted by adjusting a film thickness of the anode 23 instead of a film thickness of the resonance adjustment layer 22.

Further, the optical distance L0 may be adjusted by adjusting both of a film thickness of the resonance adjustment layer 22 and a film thickness of the anode 23.

Further, examples of a constituent material of the resonance adjustment layer 22 include inorganic materials having translucency and insulating properties. Specifically, examples thereof include silicon oxide, silicon nitride, and the like.

The plurality of anodes 23 and a partition 26 surrounding each of the anodes 23 in plan view are disposed on a surface of the resonance adjustment layer 22 on the +z side. The anode 23 is provided for each sub-pixel P0, and the anodes 23 are insulated from each other by the partition 26. Note that the partition 26 has a lattice shape in plan view, for example. Further, the anode 23 is electrically coupled to the relay electrode 321 via a through electrode 3212 disposed in a contact hole that penetrates the resonance adjustment layer 22.

Further, the constituent material of the anode 23 is a transparent conductive material such as Indium Tin Oxide (ITO) or Indium Zinc Oxide (IZO), for example. Further, the constituent material of the partition 26 is an insulating material, and specifically, is an inorganic material such as an acrylic-based photosensitive resin or silicon oxide.

The organic layer 24 is disposed on a surface of the anode 23 on the +z side. The organic layer 24 includes at least a light-emitting layer 240 containing a light-emitting material that emits light by supplying current. In the present embodiment, the light-emitting layer 240 includes lamination of a layer containing a blue light-emitting material, a layer containing a green light-emitting material, and a layer containing a red light-emitting material. Blue light is generated from the layer containing the blue light-emitting material, green light is generated from the layer containing the green light-emitting material, and red light is generated from the layer containing the red light-emitting material. Therefore, it can be said that white light is generated from the light-emitting layer 240. Further, in addition to the light-emitting layer 240, a hole injection layer (HIL), a hole transportation layer (HTL), an electron injection layer (EIL), and an electron transportation layer (ETL) are provided in the present embodiment. In the organic layer 24, holes injected from the hole injection layer and electrons transported from the electron transportation layer are recombined in the light-emitting layer 240. Note that any configuration may be used for the configuration of the organic layer 24, and any of the layers described above may be omitted from the organic layer 24, or any layer may be further added.

The cathode 25 is disposed on a surface of the organic layer 24 on the +z side. The cathode 25 has translucency and light reflectivity. The cathode 25 is a common electrode formed continuously across the plurality of sub-pixels P0. The cathode 25 is formed by, for example, magnesium and silver, or an alloy including these materials as main components, and the like.

In the light-emitting portion 2, light in a predetermined wavelength region of light generated from the organic layer 24 is caused to resonate between the reflection layer 21 and the cathode 25. When a peak wavelength of a spectrum of the light in the predetermined wavelength region is represented by λ0, the following relationship [1] holds true. Φ (radian) represents a sum total of phase shifts that occur in transmitting and reflecting within the light-emitting portion 2.

{(2×L0)/λ0+Φ}=m0(m0 is an integer) [1]

The optical distance L0 is set such that a peak wavelength of light in a wavelength region to be extracted is λ0. Then, by setting a film thickness of each of the resonance adjustment layer 22 and the anode 23 in accordance with the optical distance L0, the light in the predetermined wavelength region to be extracted is caused to resonate and enhanced. The light in the predetermined wavelength region is enhanced by adjusting the optical distance L0 in accordance with the light in the wavelength region to be extracted, and the light can be increased in intensity and a spectrum of the light can be narrowed.

Protecting Portion 4

The protecting portion 4 is disposed on the cathode 25, and seals the light-emitting portion 2. The organic layer 24 can be protected from moisture, oxygen, or the like in the atmosphere by providing the protecting portion 4. In other words, the protecting portion 4 has gas barrier properties. Thus, reliability of the display panel 1 can be increased as compared to a case in which the protecting portion 4 is not provided. Further, the protecting portion 4 has translucency.

The protecting portion 4 includes a first layer 41 disposed on the cathode 25, a second layer 42 disposed on the first layer 41, and a third layer 43 disposed on the second layer.

The first layer 41 is mainly composed of a silicon-based inorganic material containing nitrogen. The terms “mainly composed” mean that greater than or equal to 70% of a constituent material of the first layer 41 is a silicon-based inorganic material containing nitrogen. Examples of the silicon-based inorganic material containing nitrogen include silicon oxynitride or silicon nitride. Particularly, when the first layer 41 is mainly composed of silicon nitride, the gas barrier properties of the first layer 41 can be increased further than those when the first layer 41 is mainly composed of silicon oxide.

Further, the first layer 41 is formed by using a chemical vapor deposition (CVD) method using plasma. The first layer 41 having a sufficiently thin thickness can be easily formed by using the CVD method. Further, a film formation speed can be increased by using the CVD method as compared to a case in which an atomic layer deposition (ALD) method is used. Further, a film can be formed at a lower temperature by using plasma in the CVD method as compared to a case in which the plasma is not used, and stress of the first layer 41 can be reduced by adjusting the amount of gas.

A thickness D1 of the first layer 41 is preferably greater than or equal to 50 nm and less than or equal to 500 nm, is more preferably greater than or equal to 70 nm and less than or equal to 400 nm, and is even more preferably greater than or equal to 100 nm and less than or equal to 300 nm. When the thickness is within such a range, the gas barrier properties of the first layer 41 can be particularly increased, and a risk of cracking due to the thickness Dl of the first layer 41 becoming excessively thick can be reduced. Note that the thickness D1 is an average thickness of the first layer 41.

The second layer 42 is disposed on the first layer 41. The second layer 42 is mainly composed of silicon oxide such as silicon dioxide. The terms “mainly composed” mean that greater than or equal to 70% of a constituent material of the second layer 42 is silicon oxide. Even when a defect such as a pinhole occurs in the first layer 41 during manufacturing, the defect can be complemented by providing the second layer 42. Thus, it is possible to particularly effectively suppress transmission of moisture and the like in the atmosphere to the organic layer 24 with, as a path, a defect such as a pinhole that may occur in the first layer 41. Thus, a sealing function of the protecting portion 4 can be increased by providing the second layer 42. Further, resistance of the second layer 42 to water can be increased by forming the second layer 42 mainly composed of silicon oxide as compared to a case in which the second layer 42 is mainly composed of alumina. Thus, even when washing treatment, wet etching, or the like is performed during manufacturing of the display panel 1, the second layer 42 dissolving in water can be suppressed or prevented. As a result, the second layer 42 dissolving in water and a decreasing sealing function of the protecting portion 4 can be suppressed or prevented. Further, the second layer 42 may be mainly composed of silicon oxide because translucency is higher than that when the second layer 42 is mainly composed of silicon nitride.

Further, the second layer 42 is formed by using the ALD method using plasma. The function of complementing a defect in the first layer 41 can be particularly suitably exhibited by forming the second layer 42 by using the ALD method. Further, a film can be formed at a lower temperature by using plasma in the ALD method as compared to a case in which the plasma is not used.

A thickness D2 of the second layer 42 is preferably greater than or equal to 10 nm and less than or equal to 100 nm, is more preferably greater than or equal to 15 nm and less than or equal to 90 nm, and is even more preferably greater than or equal to 20 nm and less than or equal to 80 nm. When the thickness is within such a range, the function of complementing a defect in the first layer 41 can be significantly exhibited, and formation time of the second layer 42 becoming excessively long can also be suppressed. Note that the thickness D2 is an average thickness of the second layer 42.

The third layer 43 is disposed on the second layer 42.

The third layer 43 is mainly composed of a silicon-based inorganic material containing nitrogen. The terms “mainly composed” mean that greater than or equal to 70% of a constituent material of the third layer 43 is a silicon-based inorganic material containing nitrogen. By providing the third layer 43 in addition to the first layer 41 and the second layer 42, the gas barrier properties of the protecting portion 4 can be increased further than those when the third layer 43 is not provided. Further, it is easy to optimize a distance between the color filter layer 6 and the light-emitting element 20. Further, the third layer 43 is formed by using the CVD method using plasma, similarly to the first layer 41. The third layer 43 having a sufficiently thin thickness can be easily formed by using the CVD method. The third layer 43 may be particularly formed of only a silicon-based inorganic material containing nitrogen, similarly to the first layer 41.

A thickness D3 of the third layer 43 is preferably greater than or equal to 200 nm and less than or equal to 1000 nm, is more preferably greater than or equal to 250 nm and less than or equal to 800 nm, and is even more preferably greater than or equal to 200 nm and less than or equal to 600 nm. When the thickness is within such a range, the gas barrier properties of the third layer 43 can be particularly increased, and a risk of cracking due to the thickness D3 of the third layer 43 becoming excessively thick can be reduced. Note that the thickness D3 is an average thickness of the third layer 43.

The thickness D1 of the first layer 41, the thickness D2 of the second layer 42, and the thickness D3 of the third layer 43 preferably satisfy a relationship of D2<D1<D3, and more preferably satisfy a relationship of D2<(D1/2)<(D3/1.5). The protecting portion 4 having excellent sealing performance and a sufficiently thin thickness can be achieved by satisfying the relationship.

Further, the protecting portion 4 is formed of a silicon-based inorganic material containing nitrogen or a layer mainly composed of silicon oxide, and does not include a layer mainly composed of an organic material. Thus, the protecting portion 4 having a sufficiently thin thickness can be achieved as compared to a case in which the protecting portion 4 includes a layer mainly composed of an organic material. Further, mechanical shock or the like applied to the light-emitting portion 2 from the outside can be mitigated. Furthermore, when a layer mainly composed of an organic material is provided, there is a risk that a component of the protecting portion 4 enters the organic layer 24. However, such a risk can be prevented by forming the protecting portion 4 mainly composed of a silicon-based inorganic material containing nitrogen or silicon oxide.

Further, the first layer 41 and the third layer 43 may be made of only silicon nitride, and the second layer 42 may be made of only silicon oxide. However, another material may be included to the extent that the function of each layer is not reduced.

Color Filter Layer 6

The color filter layer 6 is disposed on the protecting portion 4. The color filter layer 6 corresponds to light in a predetermined wavelength region, and selectively transmits the light in the predetermined wavelength region. The color filter layer 6 includes a colored layer 61B corresponding to the sub-pixel PB, a colored layer 61G corresponding to the sub-pixel PG, and a colored layer 61R corresponding to the sub-pixel PR. In the light-emitting region A10, the colored layer 61B, the colored layer 61G, and the colored layer 61R are aligned along the x-y plane.

The color filter layer 6 is formed of a resin material including a colored material of each color. Specifically, for example, the color filter layer 6 may be formed of an acrylic photosensitive resin material. Note that the display panel 1 may have a configuration in which the color filter layer 6 is omitted. However, color purity of light emitted from the display panel 1 can be increased by providing the color filter layer 6 in the display panel 1 as compared to a case in which the color filter layer 6 is not provided.

Transmissive Substrate 7

The transmissive substrate 7 is disposed on the color filter layer 6 via an adhesive layer 70 having translucency. The transmissive substrate 7 is a cover that protects the color filter layer 6, the light-emitting element 20, and the like. The transmissive substrate 7 has translucency and is formed of, for example, a glass substrate or a quartz substrate. The adhesive layer 70 may be formed of any material as long as the material allows the transparent substrate 7 to adhere to the color filter layer 6 and has translucency. The adhesive layer 70 is formed of, for example, a transparent resin material such as epoxy resin and acrylic resin. Note that when the color filter layer 6 is omitted, the transparent substrate 7 adheres to the protecting portion 4.

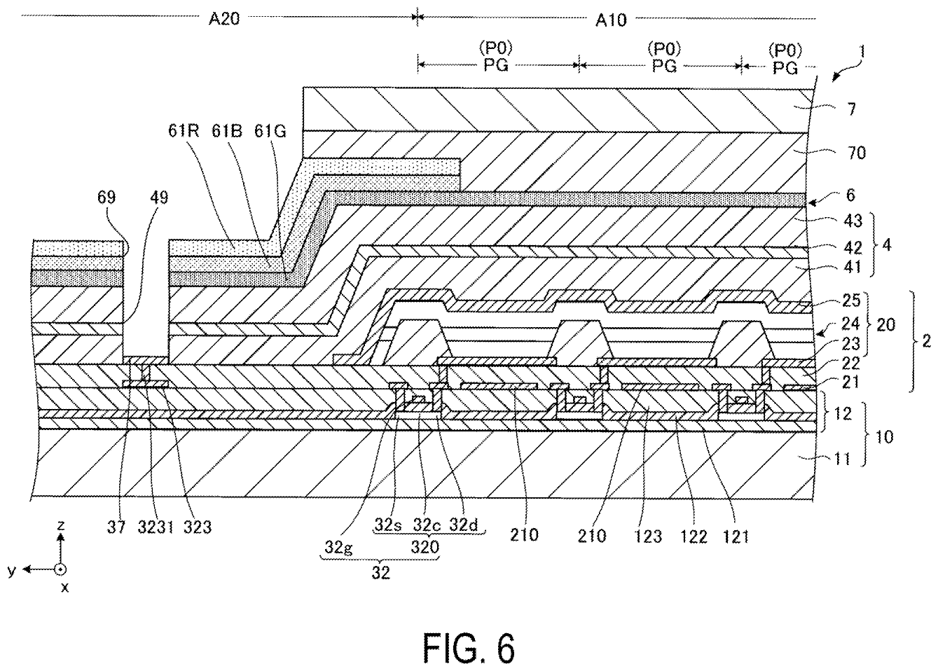

Next, the terminal 37 of the display panel 1 and a surrounding structure thereof will be described with reference to FIG. 6. FIG. 6 is a partial cross-sectional view of the display panel 1 according to the first embodiment, and is a cross-sectional view of the display panel 1 taken along a B-B line in FIG. 2.

The terminal 37 is disposed on a surface of the resonance adjustment layer 22 on the +z side. The terminal 37 is electrically coupled to a relay electrode 323 via a through electrode 3231 disposed in a contact hole that penetrates the resonance adjustment layer 22. Although not illustrated in detail, the relay electrode 323 is electrically coupled to various wiring lines and the like provided in the wiring layer 12.

An opening 49 that overlaps the plurality of terminals 37 in plan view is provided in the protecting portion 4. The opening 49 is a space that penetrates the protecting portion 4. Further, a portion of the color filter layer 6 located in the non-light-emitting region A20 is a laminate in which the colored layer 61G, the colored layer 61B, and the colored layer 61R are laminated in this order from the protecting portion 4 side. The portion of the color filter layer 6 is provided to prevent reflected light and prevent an effect of stray light. On the other hand, a portion of the color filter layer 6 located in the light-emitting region A10 functions as a color filter that transmits light having a predetermined wavelength, as described above. Further, a second opening 69 that overlaps the plurality of terminals 37 in plan view is provided in the color filter layer 6. The second opening 69 is a space that penetrates the color filter layer 6 and communicates with the opening 49. Note that the color filter layer 6 around the plurality of terminals 37 may be omitted.

The transmissive substrate 7 is disposed so as not to overlap the plurality of terminals 37 in plan view. A planar area of the transmissive substrate 7 is smaller than a planar area of the substrate 10. The transmissive substrate 7 is disposed in a region corresponding to the light-emitting region A10 in plan view.

As described above, the display panel 1 having the configuration described above includes the substrate 10, the light-emitting element 20 as an “organic EL element” disposed on the substrate 10, the first layer 41 that is disposed on a side opposite to the substrate 10 with respect to the light-emitting element 20 and is mainly composed of a silicon-based inorganic material containing nitrogen, and the second layer 42 that is disposed on a side opposite to the light-emitting element 20 with respect to the first layer 41 and is mainly composed of silicon oxide.

The display panel 1 having excellent gas barrier properties can be achieved by forming the first layer 41 mainly composed of a silicon-based inorganic material containing nitrogen. Furthermore, resistance of the second layer 42 to water can be increased by forming the second layer 42 mainly composed of silicon oxide as compared to a case in which the second layer 42 is mainly composed of alumina. As a result, the second layer 42 dissolving in water can be suppressed or prevented. Accordingly, a loss of sealing performance of the protecting portion 4 can be suppressed or prevented. As described above, the display panel 1 having excellent quality reliability can be provided by providing the first layer 41 and the second layer 42.

Note that the reflection layer 21 and the resonance adjusting layer 22 are disposed between the substrate 10 and the light-emitting element 20, but may be regarded as a part of the substrate 10. Further, any layer may be disposed between the substrate 10 and the light emitting 20, between the light-emitting element 20 and the first layer 41, and between the first layer 41 and the second layer 42 to the extent that the function of each portion is not impaired. The same applies between other elements of the display panel 1.

1-1D. Method for Manufacturing Organic EL Device 100

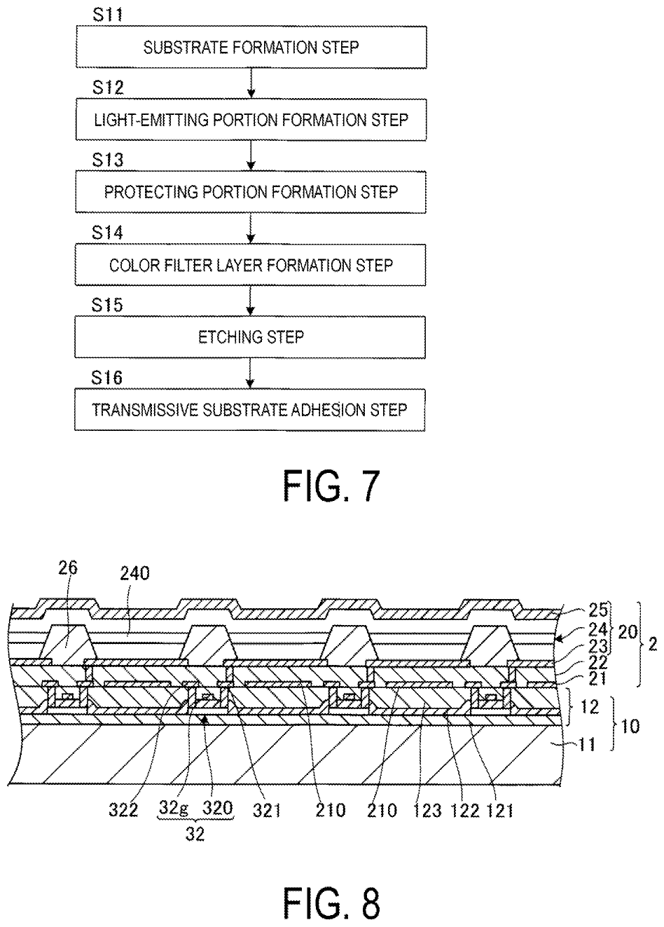

Next, a method for manufacturing the display panel 1 included in the organic EL device 100 will be described. FIG. 7 is a flowchart illustrating the method for manufacturing the display panel 1 according to the first embodiment. As illustrated in FIG. 7, the method for manufacturing the display panel 1 includes a substrate formation step S11, a light-emitting portion formation step S12, a protecting portion formation step S13, a color filter layer formation step S14, an etching step S15, and a transmissive substrate adhesion step S16. The display panel 1 is manufactured by sequentially performing each of the steps.

Substrate Formation Step S11

FIG. 8 is a cross-sectional view illustrating the substrate formation step Sll and the light-emitting portion formation step S12 according to the first embodiment. In the substrate formation step S11, the substrate main body 11 formed of a silicon plate or the like is prepared, and the wiring layer 12 is formed on the substrate main body 11. Specifically, various wiring lines and the like, such as the driving transistor 32, are formed by, for example, forming a metal film by a sputtering method or a vapor deposition method, and patterning the metal film by a photolithography method. Further, the insulating films 121, 122, and 123 are each formed by forming an insulating film by a CVD method or the like, and performing flattening treatment on the insulating film by a polishing method such as a chemical mechanical polishing (CMP) method.

Light-emitting Portion Formation Step S12

The light-emitting portion formation step S12 includes a reflection layer formation step, a resonance adjusting layer formation step, and a light-emitting element formation step as a “step of forming an organic EL element”.

First, in the reflection layer formation step, the reflection layer 21 is formed on the insulating film 123. The reflection layer 21 is formed by, for example, forming a metal film by a sputtering method or a vapor deposition method, and patterning the metal film by a photolithography method.

Further, at this time, the relay electrodes 321 and 322 are also formed. Although not illustrated, the relay electrode 323 located in the non-light-emitting region A20 is also formed.

Next, in the resonance adjustment layer formation step, the resonance adjustment layer 22 is formed on the insulating film 123 so as to cover the reflection layer 21. The resonance adjustment layer 22 is formed by, for example, forming an insulating film containing an inorganic material such as silicon oxide by a vapor phase deposition method such as a CVD method, and then performing flattening treatment.

Next, in the light-emitting element formation step, the plurality of light-emitting elements 20 are formed on the resonance adjustment layer 22. Specifically, first, the plurality of anodes 23 are formed on the resonance adjustment layer 22. The method for forming the anode 23 is similar to the method for forming the reflection layer 21. Next, the partition 26 is formed so as to surround the anode 23 in plan view.

Specifically, the partition 26 is formed by forming an insulating film by a CVD method or the like, and patterning the insulating film by a photolithography method. Next, the organic layer 24 is formed on the anode 23 and the partition 26. Each layer of the organic layer 24 is formed by, for example, a vapor deposition method. Next, the cathode 25 is formed on the organic layer 24. The method for forming the cathode 25 is similar to the method for forming the organic layer 24. As described above, the light-emitting element 20 is formed.

Protecting Portion Formation Step S13

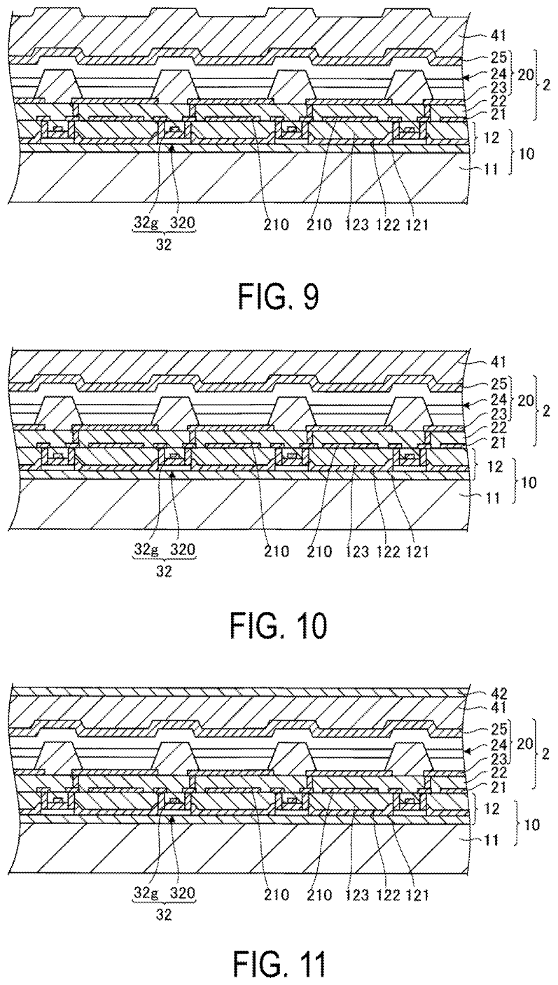

FIGS. 9 to 12 are cross-sectional views illustrating the protecting portion formation step S13 according to the first embodiment. The protecting portion formation step S13 includes a first layer formation step illustrated in FIGS. 9 and 10, a second layer formation step illustrated in FIG. 11, and a third layer formation step illustrated in FIG. 13. The first layer formation step corresponds to a “step of forming a first layer”, the second layer formation step corresponds to a “step of forming a second layer”, and the third layer formation step corresponds to a “step of forming a third layer”.

First, as illustrated in FIG. 9, in the first layer formation step, a silicon nitride film 41a is formed on the cathode 25 by an CVD method using plasma. As illustrated in FIG. 10, the first layer 41 is formed by the processing. A film formation speed can be increased by using the CVD method as compared to a case in which an ALD method is used, and thus film formation time of the first layer 41 can be shortened. Further, a film can be formed at a lower temperature by using plasma in the CVD method as compared to a case in which the plasma is not used. Further, a risk of cracking or the like generated in the first layer 41 can be reduced by reducing stress on the first layer 41. Further, in the present step, a film is formed such that a thickness of the first layer 41 falls within the above-described range.

Next, as illustrated in FIG. 11, in the second layer formation step, the second layer 42 is formed on the first layer 41 by an ALD method using plasma. A raw material for forming the second layer 42 may be an aminosilane-based material. Specifically, examples of the raw material include tris-dimethylaminosilane (SiH[N(CH₃)₂]₃), SAM24: H₂Si[N(C₂H₅)₂]₂, and the like. Note that SAM24 is a registered trademark. Further, in the ALD method, a plasma may be used, and O₂ plasma may be particularly used. A film can be formed at a lower temperature by using the O₂ plasma. As a result, stress on the second layer 42 can be reduced. By using the ALD method, even when a defect occurs in the first layer 41 formed by the CVD method, the defect can be complemented by the second layer 42 to fill the defect. Further, in the present step, a film is formed such that a thickness of the second layer 42 falls within the above-described range.

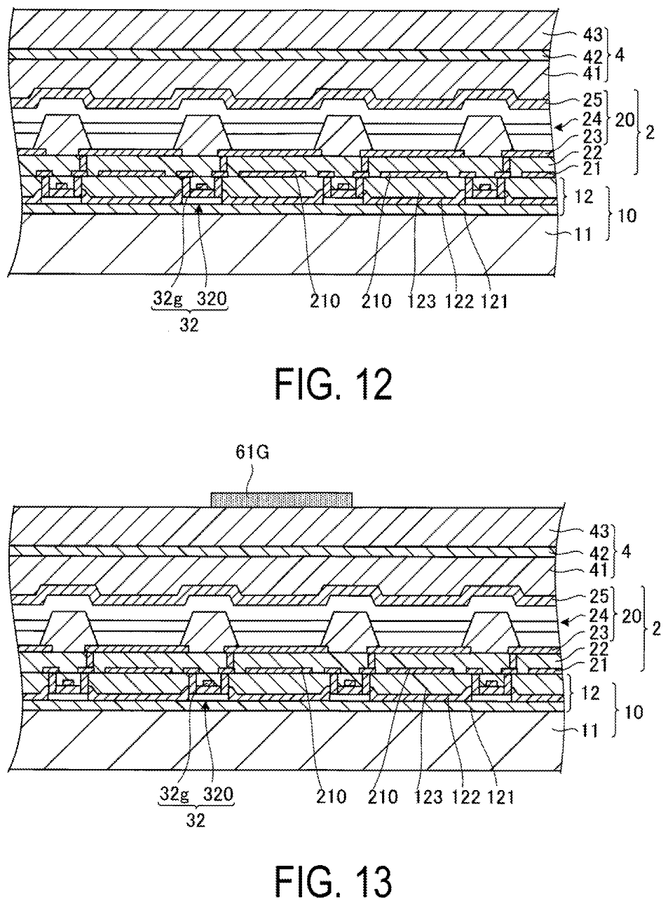

Next, as illustrated in FIG. 12, the third layer 43 is formed on the second layer 42 by a CVD method using plasma. The method for forming the third layer 43 is similar to the method for forming the first layer 41.

Color Filter Layer Formation Step S14

FIGS. 13 to 16 are each a diagram illustrating the color filter layer formation step S14 according to the first embodiment. In the color filter layer formation step S14, the color filter layer 6 is formed on the protecting portion 4.

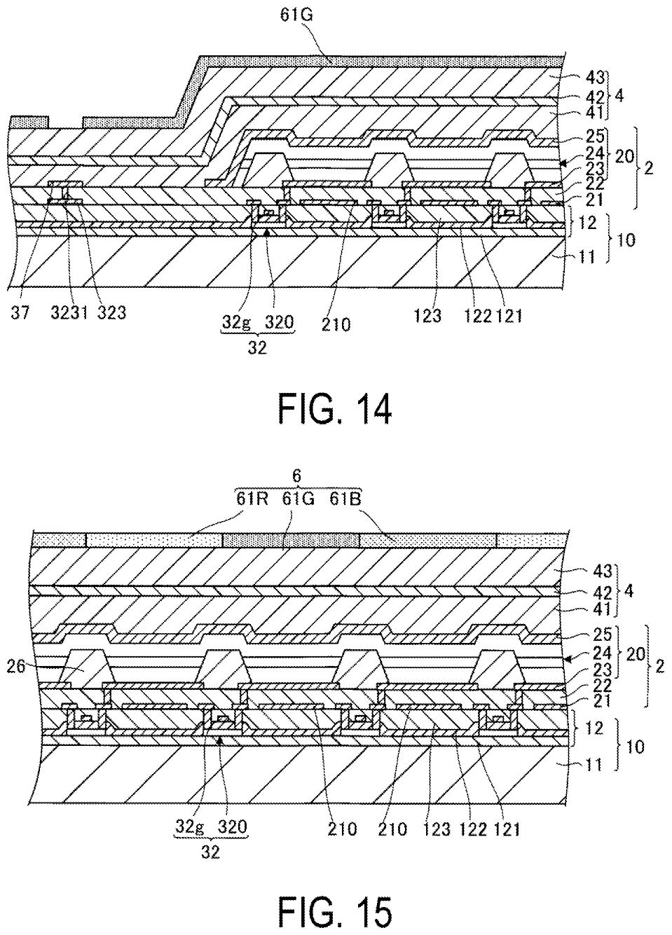

Specifically, first, the colored layer 61G illustrated in FIGS. 13 and 14 is formed. For example, a green resin layer is formed by applying a photosensitive resin containing a green color material to the third layer 43 by a spin coating method, and drying the photosensitive resin. Then, a portion of the green resin layer that forms the colored layer 61G is exposed, and an unexposed portion of the resin layer is removed by an alkaline developer or the like. Then, the colored layer 61G is formed by curing the green resin layer.

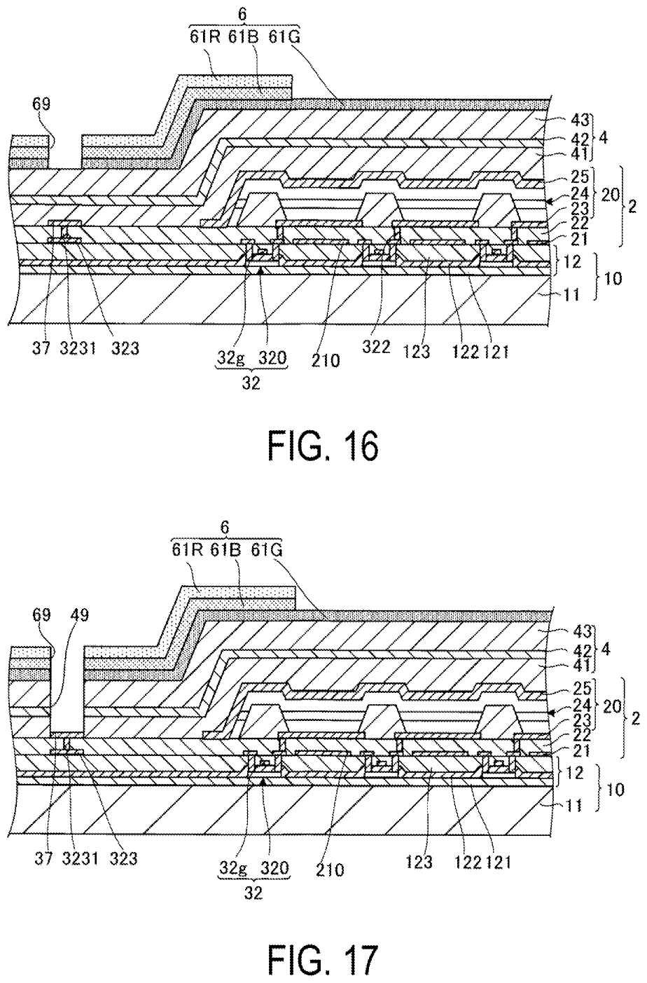

Similarly to the formation of the colored layer 61G, the colored layer 61B and the colored layer 61R illustrated in FIGS. 15 and 16 are formed. Specifically, for example, a blue resin layer is formed by applying a photosensitive resin containing a blue color material to the colored layer 61G by a spin coating method, and drying the photosensitive resin. Next, a portion of the blue resin layer that forms the colored layer 61R is exposed, and an unexposed portion of the resin layer is removed by an alkaline developer or the like. Then, the colored layer 61B is formed by curing the blue resin layer. Next, for example, a red resin layer is formed by applying a photosensitive resin containing a red color material by a spin coating method, and drying the photosensitive resin. Then, a portion of the red resin layer that forms the colored layer 61R is exposed, and an unexposed portion of the resin layer is removed by an alkali developer or the like. Then, the colored layer 61R is formed by curing the red resin layer.

As described above, as illustrated in FIG. 16, the color filter layer 6 including the second opening 69 is formed. Note that the colored layer 61G, the colored layer 61B, and the colored layer 61R in the light-emitting region A10 are formed so as to be disposed at locations different from each other on a surface of the protecting portion 4 on the +z-axis side. However, in the light-emitting region A10, the colored layer 61G, the colored layer 61B, and the colored layer 61R may have portions that partially overlap each other.

Etching Step S15

FIG. 17 is a diagram illustrating the etching step S15 according to the first embodiment. In the etching step S15, as illustrated in FIG. 17, a region corresponding to the terminal 37 of the protecting portion 4, and specifically, a region of the protecting portion 4 overlapping the terminal 37 in plan view is removed, and the opening 49 is formed. The opening 49 is formed by, for example, forming a resist pattern (not illustrated) by a photolithography method, and patterning the protecting portion 4 by dry etching by using the resist pattern as an etching mask. Since the second layer 42 is made of silicon oxide, the first layer 41, the second layer 42, and the third layer 43 can be collectively etched by using the same etching gas, which facilitates the manufacturing process. Further, examples of the etching gas used in the dry etching include CF₄ (carbon tetrafluoride), CHF₃ (carbon trifluoride), and the like.

Note that the formation of the resist pattern described above may be omitted, and, in this case, dry etching may be performed by using the color filter layer 6 including the second opening 69 as an etching mask. Further, wet etching may be performed instead of dry etching in the formation of the opening 49. Further, the etching step S15 may be performed before the color filter layer formation step S14, or may be performed after the transmissive substrate adhesion step S16.

Transmissive Substrate Adhesion Step S16

In the transmissive substrate bonding step S16, although not illustrated in detail, a transparent resin material is applied onto the color filter layer 6, and the transmissive substrate 7 formed of a glass substrate or the like is disposed on the applied resin material, and then pressed. At this time, for example, when the resin material is a photosensitive resin, the photosensitive resin is cured by irradiating with light via the transmissive substrate 7. By the curing, the adhesive layer 70 formed of a cured product of the resin material is acquired. Further, the transmissive substrate 7 adheres to the color filter layer 6 by the adhesive layer 70.

As described above, the display panel 1 of the organic EL device 100 is manufactured. Note that the organic EL device 100 is acquired by housing the display panel 1 in the case 90 and coupling the display panel 1 to the FPC substrate 95.

As described above, the method for manufacturing the display panel 1 includes the light-emitting portion formation step S12 including the light-emitting element formation step, and the protecting portion formation step S13 including the first layer formation step and the second layer formation step. In the light-emitting element formation step, the light-emitting element 20 is formed as an “organic EL element”. In the first layer formation step, the first layer 41 mainly composed of a silicon-based inorganic material containing nitrogen is formed on the light-emitting element 20 by a CVD method using plasma.

In the second layer formation step, the second layer 42 mainly composed of silicon oxide is formed on the light-emitting element 20 by an ALD method using plasma.

The display panel 1 having excellent gas barrier properties can be formed by including the step of forming the first layer 41 mainly composed of a silicon-based inorganic material containing nitrogen. Furthermore, resistance to water can be increased by including the step of forming the second layer 42 mainly composed of silicon oxide as compared to a case in which the second layer 42 is mainly composed of alumina. Thus, resistance of the second layer 42 to an alkaline developer can be increased. As a result, even when the color filter layer 6 is formed by wet etching using an alkaline developer in the formation of the color filter layer 6, the second layer 42 dissolving in water can be avoided. Further, since the resistance of the second layer 42 to water can be increased, the second layer 42 dissolving in water can be avoided even when water washing treatment or the like is performed in each of the steps. Further, as described above, even when a defect such as a pinhole occurs in the first layer 41, the defect can be complemented by forming the second layer 42 on the first layer 41. For example, there is a risk that pinholes occur at several pm of intervals in the first layer 41, but the pinholes can be filled by providing the second layer 42. Thus, it is possible to suppress transmission of moisture and the like in the atmosphere to the organic layer 24 with a pinhole as a pass. As described above, the display panel 1 having excellent quality reliability can be provided by providing the first layer 41 and the second layer 42.

Further, as described above, the protecting portion formation step S13 includes the third layer formation step. In the third layer formation step, the third layer 43 mainly composed of a silicon-based inorganic material containing nitrogen is formed on a side opposite to the first layer 41 with respect to the second layer 42 by a CVD method using plasma.

The gas barrier properties of the protecting portion 4 can be increased by providing the third layer 43 as compared to a case in which the third layer 43 is not provided. Thus, the display panel 1 having more excellent gas barrier properties can be acquired by including the step of forming the third layer 43 mainly composed of a silicon-based inorganic material containing nitrogen as compared to a case in which the step is not included.

The organic EL device 100 according to the first embodiment is described above. Note that the organic EL device 100 may be configured to emit any of light in a blue wavelength region, a green wavelength region, and a red wavelength region. In other words, the organic EL device 100 may be configured to emit only a single color.

### 1-2. Second Embodiment

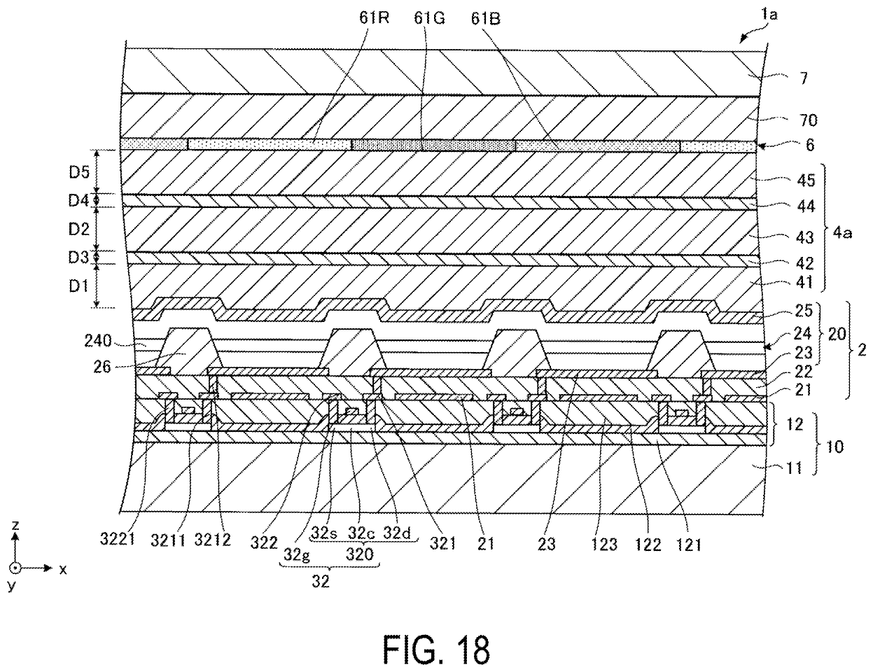

FIG. 18 is a partial cross-sectional view of a display panel la according to a second embodiment. The present embodiment is different from the first embodiment in a configuration of a protecting portion 4a. Note that, in the second embodiment, a sign used in the description of the first embodiment is used for the same matter as that of the first embodiment, and each detailed description thereof will be appropriately omitted.

The protecting portion 4a of the display panel la illustrated in FIG. 18 includes a fourth layer 44 and a fifth layer 45 in addition to a first layer 41, a second layer 42, and a third layer 43.

The fourth layer 44 is disposed on the third layer 43. The fourth layer 44 is mainly composed of silicon oxide such as silicon dioxide. The terms “mainly composed” mean that greater than or equal to 70% of a constituent material of the fourth layer 44 is silicon oxide. Even when a defect such as a pinhole occurs in the third layer 43 during manufacturing, the defect can be complemented by providing the fourth layer 44. Further, the fourth layer 44 is formed by using an ALD method using plasma, similarly to the second layer 42. A preferable range of a thickness D4 of the fourth layer 44 is similar to a preferable range of a thickness D2 of the second layer 42. Further, the thickness D4 of the fourth layer 44 may be approximately equal to the thickness D2 of the second layer 42 in terms of ease of design.

The fifth layer 45 is disposed on the fourth layer 44. The fifth layer 45 is mainly composed of a silicon-based inorganic material containing nitrogen. The terms “mainly composed” mean that greater than or equal to 70% of a constituent material of the fifth layer 45 is a silicon-based inorganic material containing nitrogen. Gas barrier properties of the protecting portion 4 can be increased by providing the fifth layer 45 as compared to a case in which the fifth layer 45 is not provided. Further, the fifth layer 45 is formed by using a CVD method using plasma, similarly to the third layer 43. A preferable range of a thickness D5 of the fifth layer 45 is similar to a preferable range of a thickness D3 of the third layer 43. Further, the thickness D5 of the fifth layer 45 may be approximately equal to the thickness D3 of the third layer 43 in terms of ease of design. The fifth layer 45 may be particularly mainly composed of silicon nitride, similarly to the third layer 43.

Further, in a method for manufacturing the display panel la, the protecting portion formation step S13 illustrated in FIG. 7 further includes a fourth layer formation step and a fifth layer formation step in addition to the first layer formation step, the second layer formation step, and the third layer formation step. In the fourth layer formation step, the fourth layer 44 mainly composed of silicon oxide is formed on a side opposite to the second layer 42 with respect to the third layer 43 by the ALD method using plasma. Further, in the fifth layer formation step, the fifth layer 45 mainly composed of a silicon-based inorganic material containing nitrogen is formed on a side opposite to the third layer 43 with respect to the fourth layer 44 by the CVD method using plasma.

Herein, there is a risk that defects occur in the second layer 42 even though the defects are extremely fewer than those in the first layer 41. For example, there is a risk that defects occur at several pm of intervals in the first layer 41, and defects occur at several cm of intervals in the second layer 42. Further, also in the third layer 43, a surface on a +z-axis side of the second layer 42 is flat, and thus defects can be reduced further than those in the first layer 41. However, since the CVD method is used for manufacturing, there is a risk that a defect and the like are more likely to occur than those when the ALD method is used. For example, there is a risk that defects occur at several cm of intervals even in the third layer 43. Thus, even when a defect such as a pinhole occurs in the third layer 43, the defect can be complemented by providing the fourth layer 44. As a result, it is possible to suppress transmission of moisture and the like in the atmosphere to an organic layer 24 with, as a pass, a defect in the third layer 43, a defect in the second layer 42, and a defect in the first layer 41 by providing the fourth layer 44. Further, the gas barrier properties of the protecting portion 4a can be further increased by including the step of forming the fifth layer 45 mainly composed of a silicon-based inorganic material containing nitrogen.

Further, by providing a plurality of groups of a layer mainly composed of a silicon-based inorganic material containing nitrogen formed by the CVD method using plasma and a layer mainly composed of silicon oxide formed by the ALD method using plasma, it is possible to reduce overlapping defects in the respective layers in plan view. As a result, a labyrinthine effect in the protecting portion 4a can be effectively exhibited. Thus, the display panel la having excellent quality reliability over a long period of time can be provided.

A total film thickness of the protecting portion 4a is not particularly limited, but is preferably greater than or equal to 500 nm and less than or equal to 2000 nm, is more preferably greater than or equal to 600 nm and less than or equal to 1800 nm, and is even more preferably greater than or equal to 700 nm and less than or equal to 1500 nm. When the total film thickness is within such a range, the protecting portion 4a having excellent sealing performance and a sufficiently thin thickness can be achieved.

### 1-3. Third Embodiment

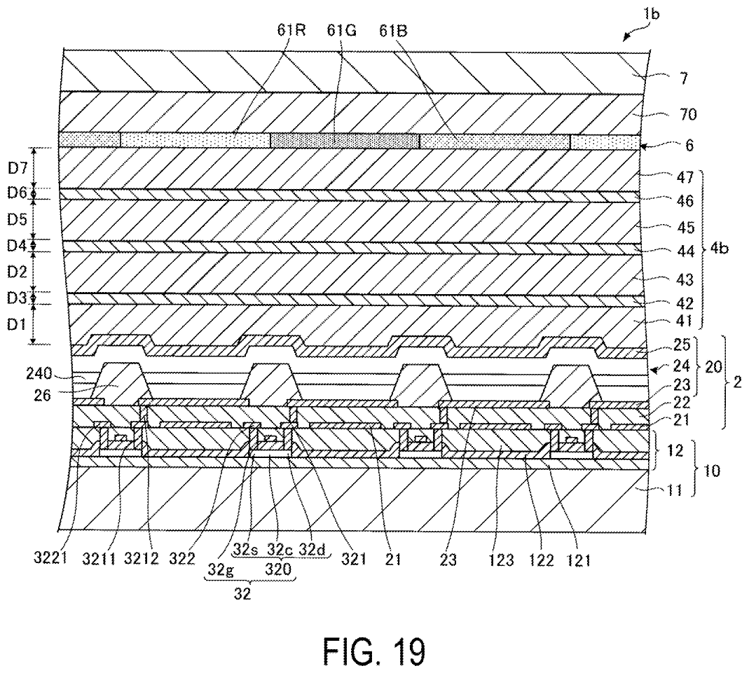

FIG. 19 is a partial cross-sectional view of a display panel lb according to a third embodiment. The present embodiment is different from the second embodiment in a configuration of a protecting portion 4b. Note that, in the third embodiment, a sign used in the description of the second embodiment is used for the same matter as that of the third embodiment, and each detailed description thereof will be appropriately omitted.

The protecting portion 4b of the display panel 1b illustrated in FIG. 19 further includes a sixth layer 46 and a seventh layer 47.

The sixth layer 46 is disposed on a fifth layer 45.

The sixth layer 46 is mainly composed of silicon oxide such as silicon dioxide. The terms “mainly composed” mean that greater than or equal to 70% of a constituent material of the sixth layer 46 is silicon oxide. Even when a defect such as a pinhole occurs in the fifth layer 45 during manufacturing, the defect can be complemented by providing the fifth layer 45. Further, the sixth layer 46 is formed by using an ALD method using plasma, similarly to a second layer 42. A preferable range of a thickness D6 of the sixth layer 46 is similar to a preferable range of a thickness D2 of the second layer 42. Further, the thickness D6 of the sixth layer 46 may be approximately equal to the thickness D2 of the second layer 42 in terms of ease of design.

The seventh layer 47 is disposed on the sixth layer 46. The seventh layer 47 is mainly composed of a silicon-based inorganic material containing nitrogen. The terms “mainly composed” mean that greater than or equal to 70% of a constituent material of the seventh layer 47 is a silicon-based inorganic material containing nitrogen. Gas barrier properties of the protecting portion 4 can be increased by providing the seventh layer 47 as compared to a case in which the seventh layer 47 is not provided. Further, the seventh layer 47 is formed by using a CVD method using plasma, similarly to a third layer 43. A preferable range of a thickness D7 of the seventh layer 47 is similar to a preferable range of a thickness D3 of the third layer 43. Further, the thickness D7 of the seventh layer 47 may be approximately equal to the thickness D3 of the third layer 43 in terms of ease of design. The seventh layer 47 may be particularly mainly composed of silicon nitride, similarly to the third layer 43.

Further, in a method for manufacturing the display panel lb, the protecting portion formation step S13 illustrated in FIG. 7 further includes a sixth layer formation step and a seventh layer formation step. In the sixth layer formation step, the sixth layer 46 mainly composed of silicon oxide is formed by the ALD method using plasma on a side opposite to a fourth layer 44 with respect to the fifth layer 45. Further, in the seventh layer formation step, the seventh layer 47 mainly composed of a silicon-based inorganic material containing nitrogen by the CVD method using plasma is formed on a side opposite to the fifth layer 45 with respect to the sixth layer 46.

Even when a defect such as a pinhole occurs in the sixth layer 46, the defect can be complemented by including the step of forming the seventh layer 47 mainly composed of silicon oxide. Further, the gas barrier properties of the protecting portion 4b can be further increased by including the step of forming the seventh layer 47 mainly composed of a silicon-based inorganic material containing nitrogen. A labyrinthine effect of the protecting portion 4b can be more effectively exhibited by providing the sixth layer 46 and the seventh layer 47.

The protecting portion 4b having excellent sealing performance over a longer period of time is acquired with an increase in the number of groups of a layer mainly composed of a silicon-based inorganic material containing nitrogen formed by the CVD method using plasma and a layer mainly composed of silicon oxide formed by the ALD method using plasma. As a result, the display panel lb having excellent quality reliability over a long period of time can be provided. Further, in terms of achieving both film thinning and sealing performance of the display panel lb, a group of a layer mainly composed of silicon oxide and a layer mainly composed of a silicon-based inorganic material containing nitrogen disposed on a first layer 41 is preferably greater than or equal to one group and less than or equal to three groups, and may be particularly two groups.

### 2. Electronic Apparatus

The organic EL device 100 of the above-described embodiments is applicable to various electronic apparatuses.

### 2-1. Head-Mounted Display

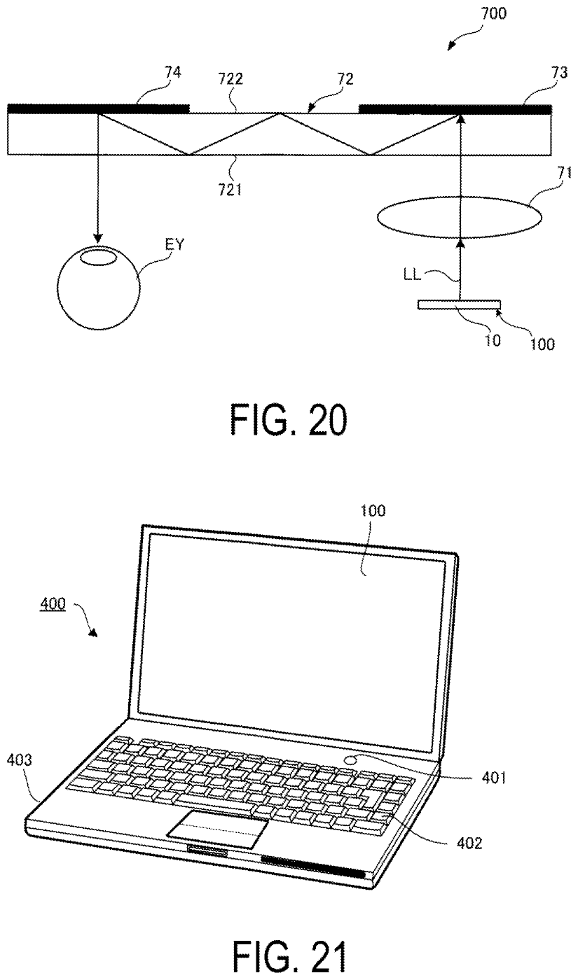

FIG. 20 is a plan view schematically illustrating a part of a virtual display apparatus 700 as an example of an electronic apparatus in the present disclosure. The virtual display apparatus 700 illustrated in FIG. 20 is a head-mounted display (HMD) mounted on a head of an observer and configured to display an image. The virtual display apparatus 700 includes the organic EL device 100 described above, a collimator 71, a light guide 72, a first reflection-type volume hologram 73, and a second reflection-type volume hologram 74. Note that light emitted from the organic EL device 100 is emitted as image light LL.

The collimator 71 is disposed between the organic EL device 100 and the light guide 72. The collimator 71 collimates light emitted from the organic EL device 100. The collimator 71 is constituted of a collimating lens or the like. The light collimated by the collimator 71 is incident on the light guide 72.

The light guide 72 has a flat plate shape, and is disposed so as to extend in a direction intersecting a direction of light incident via the collimator 71. The light guide 72 reflects and guides light therein. A light incident port on which light is incident and a light emission port from which light is emitted are provided in a surface 721 of the light guide 72 facing the collimator 71. The first reflection-type volume hologram 73 as a diffractive optical element and the second reflection-type volume hologram 74 as a diffractive optical element are disposed on a surface 722 of the light guide 72 opposite to the surface 721. The first reflection-type volume hologram 73 is provided closer to the light emission port side than the second reflection-type volume hologram 74. The first reflection-type volume hologram 73 and the second reflection-type volume hologram 74 have interference fringes corresponding to a predetermined wavelength region, and diffract and reflect light in the predetermined wavelength region.

In the virtual display apparatus 700 having such a configuration, the image light LL incident on the light guide 72 from the light incident port travels while being repeatedly reflected, and is guided to an eye EY of the observer, and thus the observer can observe an image constituted of a virtual image formed by the image light LL.

Here, the virtual display apparatus 700 includes the above-described organic EL device 100. The above-described organic EL device 100 has excellent sealing performance and good quality. Thus, a high-quality virtual display apparatus 700 can be provided by including the organic EL device 100.

Note that the virtual display apparatus 700 may include a synthetic element such as a dichroic prism configured to synthesize light emitted from the organic EL device 100. In this case, the virtual display apparatus 700 may include, for example, the organic EL device 100 configured to emit light in a blue wavelength region, the organic EL device 100 configured to emit light in a green wavelength region, and the organic EL device 100 configured to emit light in a red wavelength region.

### 2-2. Personal Computer

FIG. 21 is a perspective view illustrating a personal computer 400 as an example of the electronic apparatus in the present disclosure. The personal computer 400 includes the organic EL device 100, and a main body 403 provided with a power switch 401 and a keyboard 402. The personal computer 400 includes the above-described organic EL device 100, and thus has excellent quality.

Note that examples of the “electronic apparatus” including the organic EL device 100 include, in addition to the virtual display apparatus 700 illustrated in FIG. 20 and the personal computer 400 illustrated in FIG. 21, an apparatus arranged close to eyes such as a digital scope, a digital binocular, a digital still camera, and a video camera. Further, the “electronic apparatus” including the organic EL device 100 is applied as a mobile phone, a smartphone, a Personal Digital Assistant (PDA), a car navigation device, and a vehicle-mounted display unit. Furthermore, the “electronic device” including the organic EL device 100 is applied as illumination for illuminating light.

The present disclosure was described above based on the illustrated embodiments. However, the present disclosure is not limited thereto. In addition, the configuration of each component of the present disclosure may be replaced with any configuration that exerts the equivalent functions of the above-described embodiments, and to which any configuration may be added. Further, any configuration may be combined with each other in the above-described embodiments of the present disclosure.

What is claimed is:

1. A method for manufacturing an organic electroluminescence device, comprising:
forming an organic electroluminescence element on a substrate;
forming, on the organic electroluminescence element, a first layer mainly composed of a silicon-based inorganic material containing nitrogen by a chemical vapor deposition method using plasma; and
forming, on the first layer, a second layer mainly composed of silicon oxide by an atomic layer deposition method using plasma.

2. The method for manufacturing an organic electroluminescence device according to claim 1, further comprising
forming, on the second layer, a third layer mainly composed of a silicon-based inorganic material containing nitrogen by a chemical vapor deposition method using plasma.

3. The method for manufacturing an organic electroluminescence device according to claim 2, further comprising:
forming, on the third layer, a fourth layer mainly composed of silicon oxide by an atomic layer deposition method using plasma; and
forming, on the fourth layer, a fifth layer mainly composed of a silicon-based inorganic material containing nitrogen by a chemical vapor deposition method using plasma.

4. The method for manufacturing an organic electroluminescence device according to claim 3, further comprising:
forming, on the fifth layer, a sixth layer mainly composed of silicon oxide by an atomic layer deposition method using plasma; and
forming, on the sixth layer, a seventh layer mainly composed of a silicon-based inorganic material containing nitrogen by a chemical vapor deposition method using plasma.

5. An organic electroluminescence device, comprising:
a substrate;
an organic electroluminescence element disposed on the substrate;
a first layer disposed on a side opposite to the substrate with respect to the organic electroluminescence element, and mainly composed of a silicon-based inorganic material containing nitrogen; and
a second layer disposed on a side opposite to the organic electroluminescence element with respect to the first layer, and mainly composed of silicon oxide.

6. An electronic apparatus comprising the organic electroluminescence device according to claim 5.
